(19) United States
(12) Patent Application Publication
(10) Pub. No.: US 2025/0174842 A1
(43) Pub. Date: May 29, 2025

(54) BUSBAR MODULE

(71) Applicant: YAZAKI CORPORATION, Tokyo (JP)

(72) Inventors: Hirotaka Mukasa, Makinohara-shi (JP); Tatsuya Oga, Makinohara-shi (JP); Yoshiki Aoshima, Makinohara-shi (JP)

(21) Appl. No.: 19/041,995

(22) Filed: Jan. 31, 2025

Related U.S. Application Data
(63) Continuation of application No. PCT/JP2023/041354, filed on Nov. 16, 2023.

(30) Foreign Application Priority Data
Nov. 30, 2022 (JP) 2022-192292

(51) Int. Cl. H01M 50/519; H01M 50/505; H05K 1/02

(52) U.S. Cl. CPC H01M 50/519; H01M 50/505; H05K 1/0277

(57) ABSTRACT

A busbar module to be attached to a battery assembly includes: a first circuit body having a first wiring pattern; a second circuit body having a second wiring pattern; and electronic components each attached to a first branch line portion and a second branch line portion to each connect the first and second wiring patterns to the corresponding busbar. The first and the second wiring patterns are electrically connected at an overlapping portion of the first and second main line portions. Each of the first circuit body and the second circuit body has a slit-shaped isolation hole portion between adjacent connection points among a plurality of connection points in each of which a first contact portion and a second contact portion are connected. The isolation hole portion penetrates the overlapping portion in a thickness direction.

### CROSS-REFERENCE TO RELATED APPLICATIONS

The present application is a continuation application of PCT/JP2023/041354 that claims priority to Japanese Patent Application No. 2022-192292 filed on Nov. 30, 2022, the entire content of which is incorporated herein by reference.

### TECHNICAL FIELD

The present disclosure relates to a busbar module.

### BACKGROUND ART

In the related art, a busbar module is used, for example, to be assembled to a battery assembly (that is, a battery module in which a plurality of battery cells are stacked and arranged) that is used as a driving power source mounted on an electric vehicle, a hybrid vehicle, or the like (see, for example, JP2014-220128A).

The busbar module described in JP2014-220128A includes a plurality of busbars and voltage detection lines. The busbars are stacked, and each of the busbars connects a positive electrode and a negative electrode between adjacent battery cells. The voltage detection lines are respectively connected to the plurality of busbars and monitor the battery cells. The voltage detection line is configured to bundle a plurality of electric wires. Each of the electric wires has a general structure in which a core wire is covered with an insulating sheath.

In general, the battery cells included in the battery assembly expand and contract in a stacking direction due to operating heat associated with charging and discharging, a temperature of an external environment, and the like. As a result, the battery assembly (battery module) is also deformed to expand and contract in the stacking direction of the battery cells. Further, a size of the battery assembly in the stacking direction may generally vary for manufactured battery assemblies (that is, a manufacturing variation may occur) due to an assembly tolerance when the plurality of battery cells are stacked and arranged. Therefore, the busbar module is generally designed to have a certain margin in a length of the voltage detection line in order to cope with such deformation and manufacturing variation of the battery assembly.

However, in the busbar module in the related art described above, for example, when the number of the stacked battery cells is increased for a purpose of increasing a capacity of the battery assembly, the number of the electric wires forming the voltage detection line also increases. As a result, when the voltage detection line is formed by bundling these many electric wires, a rigidity of the voltage detection line as a whole (and thus a rigidity of the busbar module) increases, and it may be difficult to improve operability (assemblability) of assembling the busbar module to the battery assembly. For the same reason, it may also be difficult for the busbar module to extend and contract to sufficiently cope with the deformation and the manufacturing variation of the battery assembly.

### SUMMARY OF INVENTION

The present disclosure provides a busbar module excellent in assemblability to a battery assembly and adaptability to deformation and a manufacturing variation of the battery assembly.

According to an embodiment of the present disclosure, there is provided a busbar module to be attached to a battery assembly in which a plurality of single cells are stacked, and the busbar module includes:
a first circuit body that is formed of a flexible substrate having a first wiring pattern and that includes a first main line portion and a first branch line portion, the first main line portion being arranged to extend along a stacking direction of the plurality of single cells, and the first branch line portion extending to branch from the first main line portion;
a second circuit body that is formed of a flexible substrate having a second wiring pattern and that includes a second main line portion and a second branch line portion, the second main line portion being arranged to extend along the stacking direction, and the second branch line portion extending to branch from the second main line portion;
a busbar configured to connect to adjacent electrodes between the plurality of single cells;
an electronic component each attached to the first branch line portion and the second branch line portion to each connect the first wiring pattern and the second wiring pattern to the corresponding busbar; and
a holder extensible and contractible along the stacking direction and holding the first circuit body, the second circuit body, and the busbar, in which
the first wiring pattern include a plurality of first contact portions arranged in the stacking direction,
the second wiring pattern include a plurality of second contact portions arranged in the stacking direction,
the plurality of first contact portions and the plurality of second contact portions are electrically connected with each other at an overlapping portion of the first main line portion and the second main line portion, and
the first circuit body and the second circuit body each have a slit-shaped isolation hole portion between adjacent connection points among a plurality of connection points at which the first contact portions and the second contact portions are contacted, the isolation hole portion penetrating the overlapping portion in a thickness direction.

According to the busbar module of the embodiment of the present disclosure, the first circuit body and the second circuit body (hereinafter also referred to as “main lines”) formed of the flexible substrates are integrated by electrically connecting the first contact portion of the first wiring pattern and the second contact portion of the second wiring pattern at the overlapping portion of the first main line portion of the first circuit body and the second main line portion of the second circuit body. In other words, the first circuit body and the second circuit body are electrically connected to each other. The first branch line portion and the second branch line portion (hereinafter also referred to as “branch lines”) extend to respectively branch from the first main line portion and the second main line portion. Therefore, when the battery assembly expands and contracts in the stacking direction due to thermal deformation of each of the single cells, each of the busbars can move in the stacking direction of the single cells by bending or the like of the branch line. Similarly, by the bending or the like of the branch line, a variation in a size of the battery assembly in the stacking direction due to an assembly tolerance of the single cells can be absorbed. In other words, the busbar module having the present configuration can easily cope with extension and contraction and a manufacturing variation of the battery assembly by deformation of the branch line. Here, in general, even when the flexible substrate includes a large number of circuit structures, the flexible substrate is easily and flexibly deformed with a much smaller force than an electric wire used in the busbar module in the related art described above. Therefore, assemblability to the battery assembly is improved. Accordingly, the busbar module having the present configuration is more excellent in the assemblability to the battery assembly and adaptability to the deformation and the manufacturing variation of the battery assembly than the busbar module in the related art described above.

According to the busbar module having the above configuration, the first circuit body and the second circuit body are prepared as separate bodies and then electrically connected to each other. Therefore, compared to a case in which the first circuit body and the second circuit body are formed of a single continuous flexible substrate, a length of each of the first circuit body and the second circuit body in the stacking direction is shortened. Therefore, a dedicated large-sized mounting device is not required when the electronic components are attached (that is, mounted) to the first branch line portion and the second branch line portion. In other words, even when a length and a size of a final main line obtained by connecting the first circuit body and the second circuit body are not suitable for a general (general-purpose) mounting device, the first circuit body and the second circuit body may be connected to each other after the electronic component is appropriately mounted on a branch circuit body using the general (general-purpose) mounting device for each of the first circuit body and the second circuit body. Therefore, a manufacturing cost of the busbar module can be reduced.

According to the busbar module having the above configuration, since the first circuit body and the second circuit body are prepared as separate bodies and then electrically connected to each other, when the busbar module is exposed to water or the like, liquid such as the water may enter the overlapping portion of the first main line portion of the first circuit body and the second main line portion of the second circuit body (between the first main line portion and the second main line portion). However, by providing the slit-shaped isolation hole portion between the adjacent connection points in each of which the first contact portion and the second contact portion are connected, it is possible to prevent occurrence of a problem in which the adjacent connection points are conducted (short-circuited) by the liquid.

### BRIEF DESCRIPTION OF DRAWINGS

FIG. 1 is a perspective view showing a busbar module according to an embodiment of the present disclosure;

FIG. 2 is a perspective view showing a battery assembly to which the busbar module shown in FIG. 1 is to be assembled;

FIG. 3 is a perspective view showing a procedure when a first circuit body and a second circuit body included in a circuit body shown in FIG. 1 are connected and accommodated in a holder;

FIG. 4 is a perspective view showing a state in which the first circuit body and the second circuit body included in the circuit body shown in FIG. 1 are connected and accommodated in the holder;

FIG. 5 is a top view of a portion in which a connection portion of the first circuit body and a connection portion of the second circuit body shown in FIG. 4 are connected to each other (however, the holder is not shown);

FIG. 6 is a perspective view showing a procedure when a first circuit body and a second circuit body included in a circuit body according to a first modification are connected and accommodated in a holder;

FIG. 7 is a perspective view showing a state in which the first circuit body and the second circuit body shown in FIG. 6 are connected and accommodated in the holder; and

FIG. 8 is a top view of a portion in which a connection portion of the first circuit body and a connection portion of the second circuit body shown in FIG. 7 are connected to each other (however, the holder is not shown).

### DESCRIPTION OF EMBODIMENTS

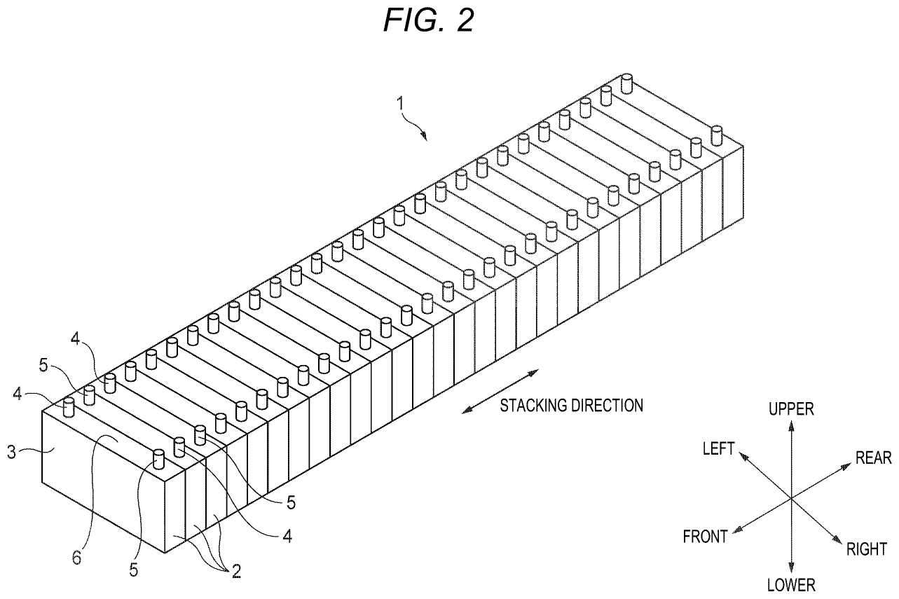

Hereinafter, a busbar module 10 according to an embodiment of the present disclosure will be described with reference to the drawings. The busbar module 10 according to the present embodiment is used, for example, to be assembled to a long battery assembly 1 (a battery module in which a plurality of single cells are stacked and arranged, see FIG. 2) that is used as a driving power source mounted on an electric vehicle.

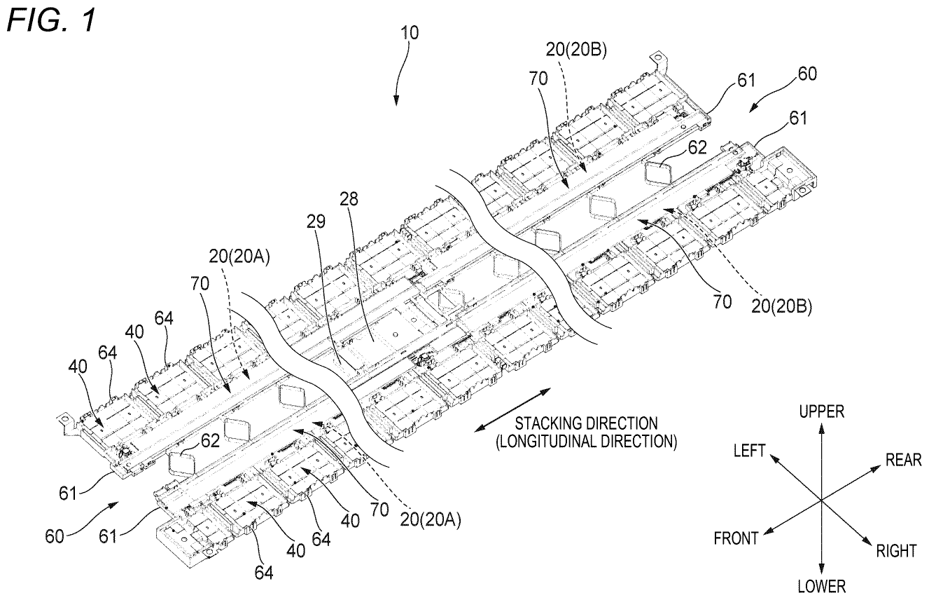

Hereinafter, for convenience of description, “front”, “rear”, “left”, “right”, “upper”, and “lower” are defined as shown in FIG. 1 and the like. A “front-rear direction”, a “left-right direction”, and an “upper-lower direction” are orthogonal to each other. The front-rear direction coincides with a stacking direction (see FIGS. 1 and 2) of a plurality of single cells 2 included in the battery assembly 1. These directions are defined for convenience of description, and do not necessarily correspond to a front-rear direction, a left-right direction, and an upper-lower direction of a vehicle when the busbar module 10 is mounted on the vehicle.

First, as preparation for describing the busbar module 10, the battery assembly 1 to which the busbar module 10 is to be attached will be described with reference to FIG. 2. As shown in FIG. 2, the battery assembly 1 is formed by stacking, in the front-rear direction, the plurality of rectangular flat plate-shaped single cells 2 each of which extends in the upper-lower direction and the left-right direction. Each of the plurality of single cells 2 includes a battery body 3 having a rectangular flat plate shape, and a positive electrode 4 and a negative electrode 5 protruding upward from both end portions in the left-right direction of an upper face 6 of the battery body 3.

In the battery assembly 1, by making positions in the left-right direction of the positive electrode 4 and the negative electrode 5 of one of the single cells 2 that are adjacent in the front-rear direction opposite to positions in the left-right direction of the positive electrode 4 and the negative electrode 5 of the other single cell 2, the plurality of single cells 2 are stacked such that the positive electrode 4 and the negative electrode 5 are alternately arranged in the front-rear direction at each of a left end portion and a right end portion of an upper face of the battery assembly 1.

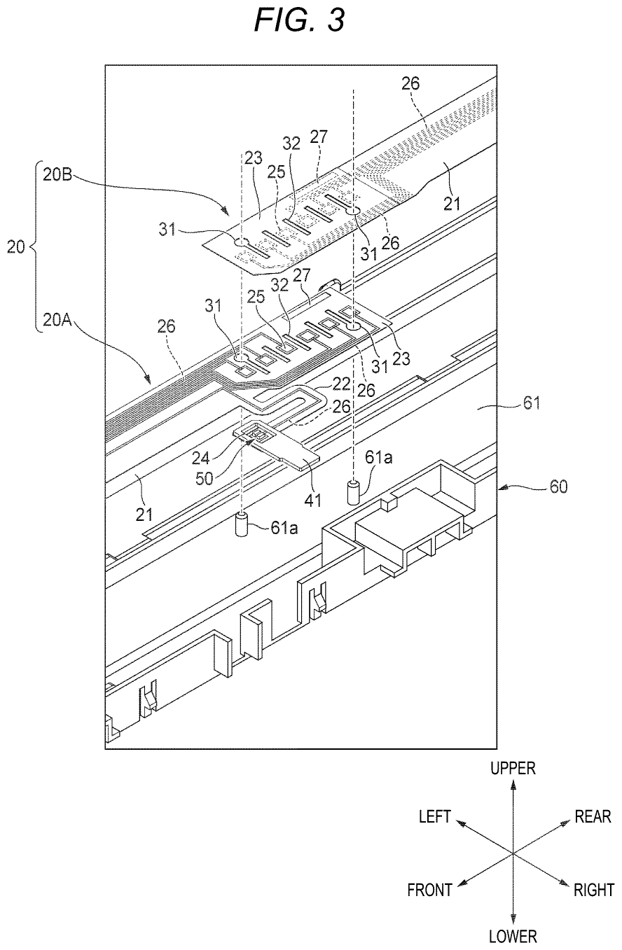

Hereinafter, the busbar module 10 will be described. As shown in FIGS. 1,3, and 4, the busbar module 10 includes a long circuit body 20 (see FIGS. 1 and 3) extending in the front-rear direction, a plurality of busbars 40 (see FIG. 1) connected to a plurality of branch line portions 22 (see FIG. 3) of the circuit body 20, a plurality of electronic components 50 (see FIG. 3) mounted on the plurality of branch line portions 22, a holder 60 (see FIGS. 1 and 3) holding the circuit body 20 and the busbars 40, and a cover 70 (see FIG. 1) covering the circuit body 20. A main line portion 21 and the branch line portion 22 (see FIG. 3) of the circuit body 20 are also referred to as a “main line” and a “branch line”, respectively.

The circuit body 20 is formed of an easily bendable flexible substrate (FPC). As can be understood from FIGS. 1 and 3, the circuit body 20 includes a pair of left and right first circuit bodies 20A and a pair of left and right second circuit bodies 20B. The left and right first circuit bodies 20A are extend in the front-rear direction and are spaced apart in the left-right direction. The left and right second circuit bodies 20B are respectively connected to rear sides of the pair of left and right first circuit bodies 20A and extend in the front-rear direction. The pair of left and right first circuit bodies 20A and the pair of left and right second circuit bodies 20B are coupled in the left-right direction by a coupling portion 28 (see FIG. 1). A connector 29 (see FIG. 1) electrically connected to an external voltage detection device (not shown) or the like is mounted on a lower face of the coupling portion 28.

Each of the first circuit body 20A and the second circuit body 20B includes the strip-shaped main line portion 21 extending in the front-rear direction, and at least one (in this example, the plurality of) branch line portion 22 extending to branch outward in the left-right direction from at least one (in this example, a plurality of) portion of the main line portion 21 in the front-rear direction (see FIG. 3). In this example, the branch line portion 22 extends from the main line portion 21 in a manner of having a U-shaped curved shape. Since the branch line portion 22 has the U-shaped curved shape, flexibility of the branch line portion 22 in the front-rear, left-right, and upper-lower directions is improved. A metal contact portion 24 is provided on an upper face of a distal end portion of the branch line portion 22 to be exposed to the outside (see FIG. 3).

By connecting a circuit connection portion 23 provided at a rear end portion of the main line portion 21 of the first circuit body 20A and the circuit connection portion 23 provided at a front end portion of the main line portion 21 of the second circuit body 20B, the circuit body 20 is formed in which the main line portion 21 of the first circuit body 20A and the main line portion 21 of the second circuit body 20B continuously extend in a row in the front-rear direction. A detailed structure of the circuit connection portion 23 of each of the first circuit body 20A and the second circuit body 20B and a connection procedure between the circuit connection portions 23 will be described later.

An entire surface of each of the first circuit body 20A and the second circuit body 20B is formed of a resin layer except for a portion (see FIG. 3) in which the contact portion 24 provided on the branch line portion 22 is exposed and portions (see FIG. 3) in which contact portions 25 that are described later and that are provided on the circuit connection portion 23 are exposed. Each of the first circuit body 20A and the second circuit body 20B includes a plurality of wiring patterns 26 (see FIG. 3). The wiring pattern 26 is a copper conductor extending in a strip shape, and extends along the main line portion 21 and the branch line portion 22. Each of the first circuit body 20A and the second circuit body 20B is a so-called “single-sided flexible substrate (single-sided FPC)” having a single wiring layer. The plurality of wiring patterns 26 are arranged on the single wiring layer of each of the first circuit body 20A and the second circuit body 20B. However, each of the first circuit body 20A and the second circuit body 20B may be a “double-sided FPC”.

At a position in which the circuit connection portion 23 of the first circuit body 20A and the circuit connection portion 23 of the second circuit body 20B are connected to each other, at least one (in this example, six) wiring pattern 26 belonging to the first circuit body 20A and at least one (in this example, six) wiring pattern 26 belonging to the second circuit body 20B are respectively and independently connected to each other (see FIG. 3).

Each of the plurality of wiring patterns 26 included in the first circuit body 20A and the second circuit body 20B is electrically connected to the connector 29 mounted on the coupling portion 28 through the contact portion 24 of corresponding one of the branch line portions 22, the corresponding branch line portion 22, the main line portion 21, and the coupling portion 28 in this order. Accordingly, the contact portions 24 of the branch line portions 22 belonging to the first circuit body 20A and the second circuit body 20B are individually conductively connected to the external voltage detection device via the connector 29 mounted on the coupling portion 28.

The distal end portion of the branch line portion 22 is mounted with the electronic component 50, and is connected with an elongated flat plate-shaped metal connection terminal 41 connected to the busbar 40 (see FIG. 3 and the like). The connection terminal 41 may be a part of the substantially rectangular flat plate-shaped metal busbar 40 (see FIG. 1), or may be a member that is a separate member from the busbar 40 and is joined to the busbar 40 by soldering or the like. The electronic component 50 is typically a chip fuse. The electronic component 50 is mounted on the distal end portion of the branch line portion 22 by soldering or the like so as to connect the contact portion 24 of the branch line portion 22 with the connection terminal 41. Accordingly, in the branch line portion 22, the contact portion 24 (that is, the wiring pattern 26 extending from the contact portion 24) and the connection terminal 41 (that is, the busbar 40) are electrically connected via the electronic component 50.

The mounting of the electronic component 50 on the branch line portion 22 is individually performed on the branch line portion 22 belonging to the first circuit body 20A and the branch line portion 22 belonging to the second circuit body 20B in a state before the circuit connection portion 23 of the first circuit body 20A and the circuit connection portion 23 of the second circuit body 20B are connected to each other (that is, in a state in which each of the first circuit body 20A and the second circuit body 20B is independent). Accordingly, compared to a case in which the first circuit body 20A and the second circuit body 20B are formed of a common (single) flexible substrate, a length of each of the first circuit body 20A and the second circuit body 20B in the front-rear direction is shortened, and thus a large mounting device is not required. In other words, since the first circuit body 20A and the second circuit body 20B are separate bodies, the electronic component 50 can be appropriately mounted on the branch line portion 22 regardless of a length and a size of the long circuit body 20 obtained by connecting the circuit connection portion 23 of the first circuit body 20A and the circuit connection portion 23 of the second circuit body 20B to each other, and a manufacturing cost of the busbar module 10 can be reduced.

Hereinafter, the detailed structure of the circuit connection portion 23 of each of the first circuit body 20A and the second circuit body 20B and the connection procedure between the circuit connection portions 23 will be described. As shown in FIG. 3, on an upper face of the circuit connection portion 23 of the first circuit body 20A, a plurality of (in this example, six) the metal contact portions (pads) 25 are provided to be arranged in a manner of being spaced apart in the front-rear direction and to be exposed to the outside. The wiring patterns 26 extend from the contact portions 25, respectively. More specifically, for each of the three contact portions 25 on a front side (proximal end side of the circuit connection portion 23) among the six contact portions 25, the wiring pattern 26 extends from the contact portion 25 to one side (left side) in a width direction (left-right direction) of the main line portion 21 of the first circuit body 20A, and then extends forward. For each of the three contact portions 25 on a rear side (distal side of the circuit connection portion 23) among the six contact portions 25, the wiring pattern 26 extends from the contact portion 25 to the other side (right side) in the width direction (left-right direction) of the main line portion 21 of the first circuit body 20A, and then extends forward.

In this way, by arranging extension portions of the plurality of wiring patterns 26 extending from the plurality of contact portions 25 in a distributed manner in the left-right direction, it is possible to contribute to improvement in a degree of freedom of a pattern design of the extension portions of the wiring patterns 26 extending from the contact portions 25, miniaturization of the circuit connection portion 23 (that is, the first circuit body 20A), and the like. On the upper face of the circuit connection portion 23 of the first circuit body 20A, a metal dummy contact portion (land) 27 is provided to be exposed to the outside at one position not interfering with the contact portions 25 and the wiring patterns 26. The dummy contact portion 27 is not connected (electrically connected) to the wiring pattern 26 (that is, the busbar 40). In the circuit connection portion 23 of the first circuit body 20A, hole portions 31 penetrating in the thickness direction (upper-lower direction) of the circuit connection portion 23 are respectively formed at a plurality of positions (in this example, two positions) not interfering with the contact portions 25, the wiring patterns 26, and the dummy contact portion 27.

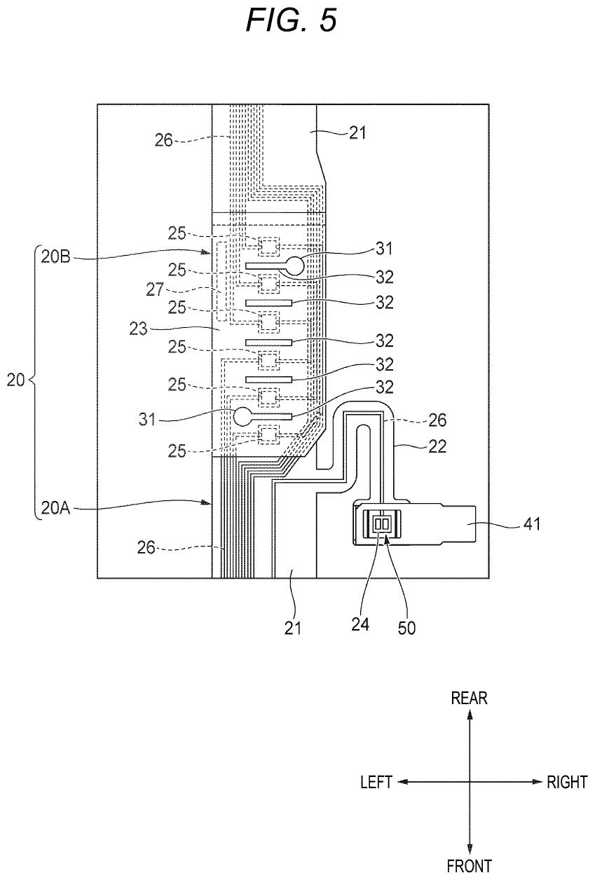

In the circuit connection portion 23 of the first circuit body 20A, slit-shaped through holes (hereinafter referred to as “isolation hole portions 32”) penetrating in the thickness direction (upper-lower direction) of the circuit connection portion 23 are respectively formed to extend in the left-right direction at positions (five positions) each of which is between the contact portions 25 adjacent to each other in the front-rear direction among the plurality of (six) contact portions 25 arranged in the front-rear direction (see FIGS. 3 and 5). Accordingly, it is possible to prevent occurrence of a problem in which the adjacent contact portions 25 are conducted (short-circuited) by moisture when the busbar module 10 is exposed to water or the like. Two isolation hole portions 32 of the five isolation hole portions 32 communicate with the two hole portions 31, respectively. Accordingly, a diameter of the isolation hole portion 32 is enlarged, and the short-circuit preventing effect described above can be further improved.

On a lower face of the circuit connection portion 23 of the second circuit body 20B, a plurality of (in this example, six) the metal contact portions (pads) 25 are provided to be arranged in a manner of being spaced apart in the front-rear direction and to be exposed to the outside, and correspond to the plurality of contact portions 25 of the first circuit body 20A. The wiring patterns 26 extend from the contact portions 25, respectively. More specifically, for each of the three contact portions 25 on a front side (distal end side of the circuit connection portion 23) among the six contact portions 25, the wiring pattern 26 extends from the contact portion 25 to the other side (right side) in the width direction (left-right direction) of the main line portion 21 of the second circuit body 20B, and then extends rearward. For each of the three contact portions 25 on a rear side (proximal end side of the circuit connection portion 23) among the six contact portions 25, the wiring pattern 26 extends from the contact portion 25 to one side (left side) in the width direction (left-right direction) of the main line portion 21 of the second circuit body 20B, and then extends rearward.

In this way, by arranging extension portions of the plurality of wiring patterns 26 extending from the plurality of contact portions 25 in a distributed manner in the left-right direction, it is possible to contribute to improvement in a degree of freedom of a pattern design of the extension portions of the wiring patterns 26 extending from the contact portions 25, miniaturization of the circuit connection portion 23 (that is, the second circuit body 20B), and the like. On the lower face of the circuit connection portion 23 of the second circuit body 20B, the metal dummy contact portion (land) 27 is provided to be exposed to the outside at one position not interfering with the contact portions 25 and the wiring patterns 26, and corresponds to the dummy contact portion 27 of the first circuit body 20A. The dummy contact portion 27 is not connected (electrically connected) to the wiring pattern 26 (that is, the busbar 40). In the circuit connection portion 23 of the second circuit body 20B, the hole portions 31 penetrating in the thickness direction (upper-lower direction) of the circuit connection portion 23 are respectively formed at a plurality of positions (in this example, two positions) not interfering with the contact portions 25, the wiring patterns 26, and the dummy contact portion 27, and correspond to the plurality of hole portions 31 of the first circuit body 20A.

In the circuit connection portion 23 of the second circuit body 20B, similarly to the isolation hole portions 32 of the first circuit body 20A, the slit-shaped isolation hole portions 32 penetrating in the thickness direction (upper-lower direction) of the circuit connection portion 23 are respectively formed to extend in the left-right direction at positions (five positions) each of which is between the contact portions 25 adjacent to each other in the front-rear direction among the plurality of (six) contact portions 25 arranged in the front-rear direction (see FIGS. 3 and 5). Accordingly, it is possible to prevent occurrence of a problem in which the adjacent contact portions 25 are conducted (short-circuited) by moisture when the busbar module 10 is exposed to water or the like. Two isolation hole portions 32 of the five isolation hole portions 32 communicate with the two hole portions 31, respectively. Accordingly, a diameter of the isolation hole portion 32 is enlarged, and the short-circuit preventing effect described above can be further improved.

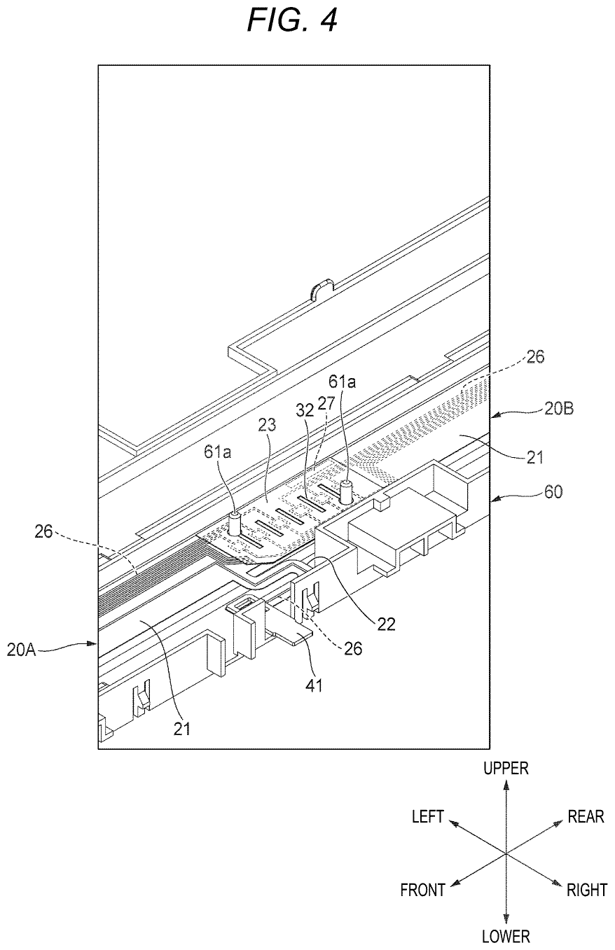

The operation of connecting the circuit connection portion 23 of the first circuit body 20A and the circuit connection portion 23 of the second circuit body 20B to each other is performed using a plurality of (in this example, two) protrusions 61a (see FIG. 3) that are provided at a plurality of (in this example, two) positions on a bottom wall of a circuit body holding portion 61 (see FIG. 3) described later of the holder 60 and that correspond to the plurality of hole portions 31 of the first circuit body 20A and the second circuit body 20B. That is, first, in a state in which the circuit connection portion 23 of the first circuit body 20A is disposed below the circuit connection portion 23 of the second circuit body 20B, each of the plurality of protrusions 61a is inserted from below into one of the plurality of hole portions 31 of the first circuit body 20A and corresponding one of the plurality of hole portions 31 of the second circuit body 20B in this order (see FIG. 4). Accordingly, the first circuit body 20A and the second circuit body 20B are accommodated in the holder 60 (circuit body holding portion 61), and a state is obtained in which the plurality of hole portions 31 of the first circuit body 20A and the plurality of hole portions 31 of the second circuit body 20B are aligned so as to overlap each other in the upper-lower direction.

Next, the plurality of contact portions 25 of the first circuit body 20A and the plurality of contact portions 25 of the second circuit body 20B are respectively and independently soldered, and the dummy contact portions 27 of the first circuit body 20A and the dummy contact portions 27 of the second circuit body 20B are soldered. Typically, the soldering can be performed by a method (so-called pulse heating method) of sandwiching a paste-like solder between the contact portions 25 arranged to face each other in the upper-lower direction and between the dummy contact portions 27 arranged to face each other in the upper-lower direction, then pressing, against a portion to be soldered, a heater chip that can heat the solder to a temperature at which the solder can be melted, and performing the soldering. The soldering may be performed by a reflow soldering method using a heating furnace. The electrical connection between the circuit connection portion 23 of the first circuit body 20A and the circuit connection portion 23 of the second circuit body 20B may be performed using a conductive adhesive instead of the soldering described above.

Accordingly, at the portion in which the circuit connection portion 23 of the first circuit body 20A and the circuit connection portion 23 of the second circuit body 20B are connected to each other, the plurality of wiring patterns 26 belonging to the first circuit body 20A and the plurality of wiring patterns 26 belonging to the second circuit body 20B are electrically connected to each other respectively and independently, and are mechanically integrated. The dummy contact portion 27 of the first circuit body 20A and the dummy contact portion 27 of the second circuit body 20B are mechanically integrated with each other using a solder, a conductive adhesive, or the like. Accordingly, the first circuit body 20A and the second circuit body 20B can be more firmly integrated.

In this way, by using the hole portion 31 of the first circuit body 20A, the hole portion 31 of the second circuit body 20B, and the protrusion 61a of the holder 60, it is possible to collectively perform an operation of accommodating the first circuit body 20A and the second circuit body 20B in the holder 60 (the circuit body holding portion 61) and an operation of electrically connecting the contact portion 25 (wiring pattern 26) of the first circuit body 20A and the contact portion 25 (wiring pattern 26) of the second circuit body 20B to each other while preventing a positional deviation or the like of both the contact portions 25 by the protrusion 61a. When an unintended external force is applied to the circuit body 20 (more specifically, the main line portion 21 of the first circuit body 20A and the main line portion 21 of the second circuit body 20B) after the connection, the external force is received by the protrusions 61a. Therefore, it is possible to prevent the external force from being applied to a connection portion of the contact portion 25 (the wiring pattern 26) of the first circuit body 20A and the contact portion 25 (the wiring pattern 26) of the second circuit body 20B. Accordingly, reliability of the electrical connection between the first circuit body 20A and the second circuit body 20B can be improved.

Next, the holder 60 will be described. The holder 60 is a resin molded product, and as shown in FIG. 1, integrally includes the pair of left and right strip-shaped circuit body holding portions 61 that are spaced apart in the left-right direction and extend in the front-rear direction, and a plurality of coupling portions 62 that couple the pair of left and right circuit body holding portions 61 in the left-right direction at a plurality of positions in the front-rear direction. The pair of left and right first circuit bodies 20A (main line portions 21 and branch line portions 22) are respectively placed on the pair of left and right circuit body holding portions 61. The pair of left and right second circuit bodies 20B (main line portions 21 and branch line portions 22) of the circuit body 20 are respectively placed on the pair of left and right circuit body holding portions 61.

Specifically, each of the pair of circuit body holding portions 61 extending in the front-rear direction includes a plurality of divided bodies (not shown) arranged side by side in the front-rear direction, and extension and contraction portions (not shown) each connecting, in the front-rear direction, the divided bodies adjacent to each other in the front-rear direction. Each of the extension and contraction portions has a shape that is easily extended and contracted in the front-rear direction due to elastic deformation. Therefore, the pair of circuit body holding portions 61 are extendable and contractible along the front-rear direction. As described above, a plurality of (two) protrusions 61a are provided on the bottom wall of the circuit body holding portion 61 (see FIG. 3).

For each of the pair of left and right circuit body holding portions 61, a busbar holding portion 64 (see FIG. 1) is integrally provided to be adjacent to the outside in the left-right direction in each of the plurality of divided bodies arranged in the front-rear direction. That is, the plurality of busbar holding portions 64 are arranged side by side in the front-rear direction on the outer side in the left-right direction of each of the pair of left and right circuit body holding portions 61. Since each of the busbar holding portions 64 is provided in corresponding one of the divided bodies, an interval in the front-rear direction between the busbar holding portions 64 adjacent to each other in the front-rear direction can be changed by a function of the extension and contraction portion.

The busbar 40 is accommodated in corresponding one of the busbar holding portions 64. When the holder 60 is attached to the battery assembly 1, the busbar 40 accommodated in the busbar holding portion 64 is conductively connected to the corresponding positive electrode 4 and negative electrode 5 that are adjacent to each other in the front-rear direction on the upper face of the battery assembly 1.

Next, the cover 70 will be described. The cover 70, which is a resin molded product, functions to cover the circuit bodies 20, that is, the first circuit bodies 20A (main line portions 21 and branch line portions 22) and the second circuit bodies 20B (main line portions 21 and branch line portions 22) placed on the pair of left and right circuit body holding portions 61 of the holder 60 which are long in the front-rear direction (see FIG. 1). Therefore, as shown in FIG. 1, the cover 70 has a strip shape formed to be long in the front-rear direction.

In an attachment completion state in which the busbar module 10 has been attached to the battery assembly 1, in the battery assembly 1, the plurality of stacked single cells 2 are electrically connected in series via the plurality of busbars 40. The busbar 40 is conductively connected to the external voltage detection device via the electronic component 50 mounted on corresponding one of the branch line portions 22, the wiring pattern 26 extending from the corresponding branch line portion 22 (contact portion 24), and the connector 29 mounted on the coupling portion 28, in this order. Accordingly, a voltage (potential) of the busbar 40 can be individually detected by the external voltage detection device. When an excessive current equal to or greater than a rated current flows in the electronic component 50 for some reason, a fuse function of the electronic component 50 will be exerted, and thus an electrical connection between the busbar 40 and the wiring pattern 26 is cut off by the electronic component 50. Accordingly, the excessive current is prevented from flowing into the external voltage detection device, so that the external voltage detection device can be protected.

In a use state of the battery assembly 1 to which the busbar module 10 has been attached, each of the single cells 2 included in the battery assembly 1 may expand or contract in the stacking direction (the front-rear direction) due to operating heat associated with charging and discharging, a temperature of an external environment, and the like. As a result, the battery assembly 1 may deform to expand and contract in the stacking direction (front-rear direction). Further, a size of the battery assembly 1 in the stacking direction (front-rear direction) may vary for the manufactured battery assemblies 1 (a manufacturing variation may occur) due to an assembly tolerance when the plurality of single cells 2 are stacked and arranged.

In this regard, in the busbar module 10, even when the extension and contraction of the battery assembly 1 in the stacking direction (front-rear direction) due to the thermal deformation of each single cell 2 and the manufacturing variation of the battery assembly 1 occur, the extension and contraction due to the thermal deformation and the manufacturing variation of the battery assembly I can be easily absorbed since each of the plurality of extension and contraction portions of the holder 60 extends and contracts in the front-rear direction and each branch line portion 22 formed of the flexible substrate is easily bent.

As described above, according to the busbar module 10 of the present embodiment, the first circuit body 20A and the second circuit body 20B (main lines) formed of the flexible substrates are integrated by electrically connecting the wiring pattern 26 of the first circuit body 20A and the wiring pattern 26 of the second circuit body 20B to each other at an overlapping portion (the circuit connection portions 23) of the main line portion 21 of the first circuit body 20A and the main line portion 21 of the second circuit body 20B. In other words, the first circuit body 20A and the second circuit body 20B are electrically connected. The branch line portions 22 (branch lines) extend to branch from the main line portion 21 of the first circuit body 20A and the main line portion 21 of the second circuit body 20B. Therefore, when the battery assembly 1 expands and contracts in the stacking direction (front-rear direction) due to the thermal deformation of each of the single cells 2, each of the busbars 40 can move in the stacking direction of the single cells 2 by bending or the like of the branch line. Similarly, by the bending or the like of the branch line, a variation in the size of the battery assembly 1 in the stacking direction (front-rear direction) due to the assembly tolerance of the single cells 2 can be absorbed. In other words, the busbar module 10 according to the present embodiment can easily cope with the expansion and contraction and the manufacturing variation of the battery assembly I due to the deformation of the branch line. Here, in general, even when the flexible substrate includes a large number of circuit structures, the flexible substrate is easily and flexibly deformed with a much smaller force than an electric wire used in the busbar module in the related art described above. Therefore, assemblability to the battery assembly 1 is improved. Accordingly, the busbar module 10 according to the present embodiment is more excellent in the assemblability to the battery assembly 1 and adaptability to the deformation and the manufacturing variation of the battery assembly 1 than the busbar module in the related art described above.

Further, the first circuit body 20A and the second circuit body 20B are prepared as separate bodies and then electrically connected to each other. Therefore, compared to a case in which the first circuit body 20A and the second circuit body 20B are formed of a single continuous flexible substrate, the length of each of the first circuit body 20A and the second circuit body 20B in the stacking direction (front-rear direction) is shortened. Therefore, a dedicated large-sized mounting device is not required when the electronic component 50 is attached (that is, mounted) to the branch line portion 22. In other words, even when a length and a size of a final main line obtained by connecting the first circuit body 20A and the second circuit body 20B are not suitable for a general (general-purpose) mounting device, the first circuit body 20A and the second circuit body 20B may be connected to each other after the electronic component 50 is appropriately mounted on the branch line portion 22 using the general (general-purpose) mounting device for each of the first circuit body 20A and the second circuit body 20B. Therefore, the manufacturing cost of the busbar module 10 can be reduced.

According to the busbar module 10 of the present embodiment, since the first circuit body 20A and the second circuit body 20B are prepared as separate bodies and then electrically connected to each other, when the busbar module 10 is exposed to water or the like, liquid such as the water may enter the overlapping portion 23 (between the main line portion 21 of the first circuit body 20A and the main line portion 21 of the second circuit body) of the main line portion 21 of the first circuit body 20A and the main line portion 21 of the second circuit body. However, by providing the slit-shaped isolation hole portion 32 between adjacent connection points in each of which the contact portion 25 of the first circuit body 20A and the contact portion 25 of the second circuit body are connected, it is possible to prevent occurrence of a problem in which the adjacent connection points are conducted (short-circuited) by the liquid.

According to the busbar module 10 of the present embodiment, by aligning the hole portion 31 of the first circuit body 20A and the hole portion 31 of the second circuit body 20B to be overlapped with each other (for example, by inserting the protrusion 61a as in this example or a rod-shaped fixture into the hole portion 31 of the first circuit body 20A and the hole portion 31 of the second circuit body 20B), it is possible to prevent the positional deviation or the like between the wiring pattern 26 of the first circuit body 20A and the wiring pattern 26 of the second circuit body 20B when both the wiring patterns 26 are electrically connected to each other (for example, soldered). Accordingly, the reliability of the electrical connection between the first circuit body 20A and the second circuit body 20B can be improved. In addition, since the hole portion 31 and the isolation hole portion 32 communicate with each other, the diameter of the isolation hole portion 32 is enlarged, and the short-circuit preventing effect described above can be further improved.

According to the busbar module 10 of the present embodiment, the holder 60 has the protrusion 61a that is inserted into the hole portion 31 of the first circuit body 20A and the hole portion 31 of the second circuit body 20B. Accordingly, it is possible to collectively perform the operation of accommodating the first circuit body 20A and the second circuit body 20B in the holder 60 and the operation of electrically connecting the wiring pattern 26 of the first circuit body 20A and the wiring pattern 26 of the second circuit body 20B to each other while regulating the positions of both the wiring patterns 26 by the protrusion 61a. When an unintended external force is applied to the main lines (the first circuit body 20A and the second circuit body 20B) after the connection, the external force is received by the protrusion 61a. Therefore, it is possible to prevent the external force from being applied to the connection portion of the wiring pattern 26 of the first circuit body 20A and the wiring pattern 26 of the second circuit body 20B. Accordingly, the reliability of the electrical connection between the first circuit body 20A and the second circuit body 20B can be improved.

According to the busbar module 10 of the present embodiment, the wiring pattern 26 of the first circuit body 20A and the wiring pattern 26 of the second circuit body 20B are conductively joined to each other by a conductive joining material. Accordingly, in addition to electrically connecting the wiring pattern 26 of the first circuit body 20A and the wiring pattern 26 of the second circuit body 20B, the first circuit body 20A and the second circuit body 20B are also mechanically integrated.

According to the busbar module 10 of the present embodiment, in addition to joining the wiring pattern 26 of the first circuit body 20A and the wiring pattern 26 of the second circuit body 20B, the dummy contact portion 27 of the first circuit body 20A and the dummy contact portion 27 of the second circuit body 20B are joined to each other. Accordingly, the first circuit body 20A and the second circuit body 20B can be more firmly integrated.

The present disclosure has been described based on the embodiment described above, but the present disclosure is not limited to the embodiment described above, and modifications, improvements, and the like can be appropriately made. In addition, materials, shapes, sizes, numbers, arrangement positions, or the like of components in the embodiment described above are freely selected and are not limited as long as the present disclosure can be implemented.

### First Modification

In the embodiment described above, the plurality of hole portions 31 are formed in each of the first circuit body 20A and the second circuit body 20B. The holder 60 is provided with protrusions 61a that are inserted into the plurality of hole portions 31.

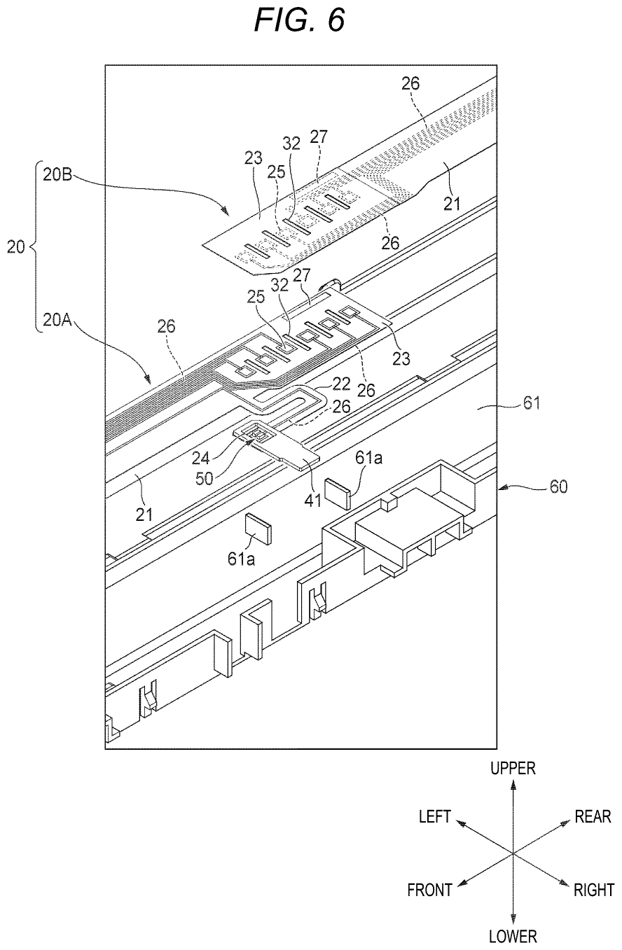

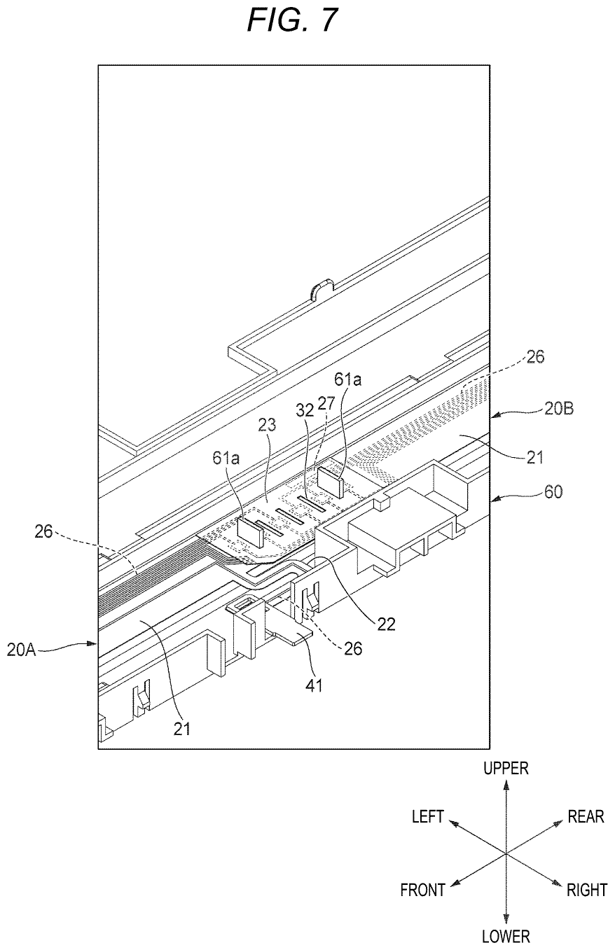

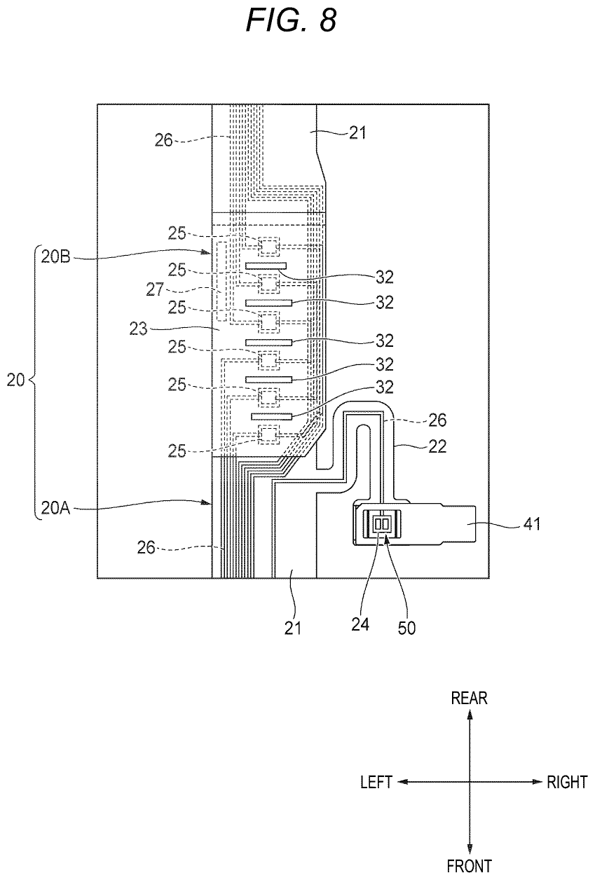

In contrast, as shown in FIGS. 6 to 8, the hole portion 31 may not be formed in each of the first circuit body 20A and the second circuit body 20B. In this case, the protrusions 61a are formed in a rib shape to correspond to the isolation hole portion 32, and the protrusions 61a are respectively inserted into the two isolation hole portions 32 at a front end and a rear end among the five isolation hole portions 32. That is, first, in a state in which the circuit connection portion 23 of the first circuit body 20A is disposed below the circuit connection portion 23 of the second circuit body 20B, the plurality of protrusions 61a are inserted from below into the plurality of isolation hole portions 32 of the first circuit body 20A and the plurality of isolation hole portions 32 of the second circuit body 20B in this order (see FIG. 7).

Accordingly, it is possible to collectively perform the operation of accommodating the first circuit body 20A and the second circuit body 20B in the holder 60 and the operation of electrically connecting the wiring pattern 26 of the first circuit body 20A and the wiring pattern 26 of the second circuit body 20B to each other while regulating the positions of both the wiring patterns 26 by the protrusion 61a. When an unintended external force is applied to the main lines (the first circuit body 20A and the second circuit body 20B) after the connection, the external force is received by the protrusion 61a. Therefore, it is possible to prevent the external force from being applied to the connection portion of the wiring pattern 26 of the first circuit body 20A and the wiring pattern 26 of the second circuit body 20B. Accordingly, the reliability of the electrical connection between the first circuit body 20A and the second circuit body 20B can be improved.

Here, features of the embodiment described above of the busbar module according to the present disclosure will be briefly summarized and listed in the following first to fourth aspects.

According to a first aspect of the present disclosure, a busbar module (10) to be attached to a battery assembly (1) in which a plurality of single cells (2) are stacked includes:
a first circuit body (20A) that is formed of a flexible substrate having a first wiring pattern (26) and that includes a first main line portion (21) and a first branch line portion (22), the first main line portion (21) being arranged to extend along a stacking direction of the plurality of single cells (2), and the first branch line portion (22) extending to branch from the first main line portion (21);
a second circuit body (20B) that is formed of a flexible substrate having a second wiring pattern (26) and that includes a second main line portion (21) and a second branch line portion (22), the second main line portion (21) being arranged to extend along the stacking direction, and the second branch line portion (22) extending to branch from the second main line portion (21);
a busbar (40) configured to connect to adjacent electrodes (4, 5) between the plurality of single cells (2);
an electronic component (50) each attached to the first branch line portion (22) and the second branch line portion (22) to each connect the first wiring pattern (26) and the second wiring pattern (26) to the corresponding busbar (40); and
a holder (60) extensible and contractible along the stacking direction and holding the first circuit body (20A), the second circuit body (20B), and the busbar (40), in which
the first wiring pattern (26) include a plurality of first contact portions (25) arranged in the stacking direction,
the second wiring pattern (26) include a plurality of second contact portions (25) arranged in the stacking direction,
the plurality of first contact portions (25) and the plurality of second contact portions (25) are electrically connected with each other at an overlapping portion (23) of the first main line portion (21) and the second main line portion (21), and
the first circuit body (20A) and the second circuit body (20B) each have a slit-shaped isolation hole portion (32) between adjacent connection points among a plurality of connection points at which the first contact portions (25) and the second contact portions (25) are contacted, the isolation hole portion (32) penetrating the overlapping portion (23) in a thickness direction.

According to the busbar module having the configuration of the above first aspect, the first circuit body and the second circuit body (hereinafter also referred to as “main lines”) formed of the flexible substrates are integrated by electrically connecting the first contact portion of the first wiring pattern and the second contact portion of the second wiring pattern at the overlapping portion of the first main line portion of the first circuit body and the second main line portion of the second circuit body. In other words, the first circuit body and the second circuit body are electrically connected to each other. The first branch line portion and the second branch line portion (hereinafter also referred to as “branch lines”) extend to respectively branch from the first main line portion and the second main line portion. Therefore, when the battery assembly expands and contracts in the stacking direction due to the thermal deformation of each of the single cells, each of the busbars can move in the stacking direction of the single cells by bending or the like of the branch line. Similarly, by the bending or the like of the branch line, the variation in the size of the battery assembly in the stacking direction due to the assembly tolerance of the single cells can be absorbed. In other words, the busbar module having the present configuration can easily cope with the extension and contraction and the manufacturing variation of the battery assembly by the deformation of the branch line. Here, in general, even when the flexible substrate includes a large number of circuit structures, the flexible substrate is easily and flexibly deformed with a much smaller force than an electric wire used in the busbar module in the related art described above. Therefore, the assemblability to the battery assembly is improved. Accordingly, the busbar module having the present configuration is more excellent in the assemblability to the battery assembly and adaptability to the deformation and the manufacturing variation of the battery assembly than the busbar module in the related art described above.

According to the busbar module having the above configuration, among the plurality of first contact portions arranged in the stacking direction of the plurality of single cells, a first wiring portion extends from a first contact portion to one side in a direction, and a first wiring portion extends from another first contact portion to the other side in a direction intersecting with the above direction. Accordingly, by arranging the plurality of first wiring portions extending from the plurality of first contact portions in a distributed manner in the directions intersecting with each other, it is possible to contribute to improvement in a degree of freedom of a pattern design of the first wiring portions, miniaturization of the first circuit body, and the like. The same applies to the second wiring pattern of the second circuit body. In addition, the first circuit body and the second circuit body are prepared as separate bodies and then electrically connected to each other. Therefore, compared to a case in which the first circuit body and the second circuit body are formed of a single continuous flexible substrate, a length of each of the first circuit body and the second circuit body in the stacking direction is shortened. Therefore, a dedicated large-sized mounting device is not required when the electronic components are attached (that is, mounted) to the first branch line portion and the second branch line portion. In other words, even when the length and the size of the final main line obtained by connecting the first circuit body and the second circuit body are not suitable for a general (general-purpose) mounting device, the first circuit body and the second circuit body may be connected to each other after the electronic component is appropriately mounted on the branch circuit body using the general (general-purpose) mounting device for each of the first circuit body and the second circuit body. Therefore, the manufacturing cost of the busbar module can be reduced.

According to the busbar module having the above configuration, since the first circuit body and the second circuit body are prepared as separate bodies and then electrically connected to each other, when the busbar module is exposed to water or the like, liquid such as the water may enter the overlapping portion of the first main line portion of the first circuit body and the second main line portion of the second circuit body (between the first main line portion and the second main line portion). However, by providing the slit-shaped isolation hole portion between the adjacent connection points in each of which the first contact portion and the second contact portion are connected, it is possible to prevent occurrence of a problem in which the adjacent connection points are conducted (short-circuited) by the liquid.

According to a second aspect of the present disclosure, in the busbar module (10) according to the above first aspect,
the first circuit body (20A) has a first hole portion (31) penetrating the first circuit body (20A) in the thickness direction,
the second circuit body (20B) has a second hole portion (31) penetrating the second circuit body (20B) in the thickness direction,
the first contact portions (25) and the second contact portions (25) are electrically connected in a state where the first hole portion (31) and the second hole portion (31) are aligned to overlap each other, and
the first hole portion (31) and the second hole portion (31) communicate with the isolation hole portion (32).

According to the busbar module having the configuration of the above second aspect, by aligning the first hole portion of the first circuit body and the second hole portion of the second circuit body to be overlapped with each other (for example, by inserting the rod-shaped fixture into the first hole portion and the second hole portion), it is possible to prevent a positional deviation or the like between the first wiring pattern and the second wiring pattern when both the wiring patterns are electrically connected (for example, soldered). Since at least one of the first hole portion and the second hole portion communicates with the isolation hole portion, a diameter of the isolation hole portion is enlarged, and the short-circuit preventing effect described above can be further improved. The communicating hole portion can be used for aligning.

According to a third aspect of the present disclosure, in the busbar module (10) according to the above second aspect,
the holder (60) includes a protrusion (61a) inserted into the first hole portion (31) and the second hole portion (31).

According to the busbar module having the configuration of the above third aspect, the holder has the protrusion that is inserted into the first hole portion of the first circuit body and the second hole portion of the second circuit body. Accordingly, it is possible to collectively perform an operation of accommodating the first circuit body and the second circuit body in the holder and an operation of electrically connecting the wiring pattern of the first circuit body and the wiring pattern of the second circuit body to each other while regulating the positions of both the wiring patterns by the protrusion. When an unintended external force is applied to the main lines (the first circuit body and the second circuit body) after the connection, the external force is received by the protrusion. Therefore, it is possible to prevent the external force from being applied to the connection portion of the wiring pattern of the first circuit body and the wiring pattern of the second circuit body. Accordingly, reliability of the electrical connection between the first circuit body and the second circuit body can be improved.

According to a fourth aspect of the present disclosure, in the busbar module (10) according to the above first to third aspects,
the holder includes a protrusion inserted into the isolation hole portion.

According to the busbar module having the configuration of the above fourth aspect, the holder has the protrusion that is inserted into the isolation hole portion. Accordingly, it is possible to collectively perform the operation of accommodating the first circuit body and the second circuit body in the holder and the operation of electrically connecting the wiring pattern of the first circuit body and the wiring pattern of the second circuit body to each other while regulating the positions of both the wiring patterns by the protrusion. When an unintended external force is applied to the main lines (the first circuit body and the second circuit body) after the connection, the external force is received by the protrusion. Therefore, it is possible to prevent the external force from being applied to the connection portion of the wiring pattern of the first circuit body and the wiring pattern of the second circuit body. Accordingly, the reliability of the electrical connection between the first circuit body and the second circuit body can be improved.

Although the present disclosure has been described in detail with reference to the specific embodiments, it is apparent to those skilled in the art that various changes and modifications can be made without departing from the spirit and scope of the present disclosure.

The present application is based on a Japanese patent application (Japanese Patent Application No. 2022-192292) filed on Nov. 30, 2022, contents of which are incorporated herein by reference.

What is claimed is:

1. A busbar module to be attached to a battery assembly in which a plurality of single cells are stacked, the busbar module comprising:
a first circuit body that is formed of a flexible substrate having a first wiring pattern and that includes a first main line portion and a first branch line portion, the first main line portion being arranged to extend along a stacking direction of the plurality of single cells, and the first branch line portion extending to branch from the first main line portion;
a second circuit body that is formed of a flexible substrate having a second wiring pattern and that includes a second main line portion and a second branch line portion, the second main line portion being arranged to extend along the stacking direction, and the second branch line portion extending to branch from the second main line portion;
a busbar configured to connect to adjacent electrodes between the plurality of single cells;
an electronic component each attached to the first branch line portion and the second branch line portion to each connect the first wiring pattern and the second wiring pattern to the corresponding busbar; and
a holder extensible and contractible along the stacking direction and holding the first circuit body, the second circuit body, and the busbar, wherein
the first wiring pattern include a plurality of first contact portions arranged in the stacking direction,
the second wiring pattern include a plurality of second contact portions arranged in the stacking direction,
the plurality of first contact portions and the plurality of second contact portions are electrically connected with each other at an overlapping portion of the first main line portion and the second main line portion, and
the first circuit body and the second circuit body each have a slit-shaped isolation hole portion between adjacent connection points among a plurality of connection points at which the first contact portions and the second contact portions are contacted, the isolation hole portion penetrating the overlapping portion in a thickness direction.

2. The busbar module according to claim 1, wherein
the first circuit body has a first hole portion penetrating the first circuit body in the thickness direction,
the second circuit body has a second hole portion penetrating the second circuit body in the thickness direction,
the first contact portions and the second contact portions are electrically connected in a state where the first hole portion and the second hole portion are aligned to overlap each other, and
the first hole portion and the second hole portion communicate with the isolation hole portion.

3. The busbar module according to claim 2, wherein
the holder includes a protrusion inserted into the first hole portion and the second hole portion.

4. The busbar module according to claim 1, wherein
the holder includes a protrusion inserted into the isolation hole portion.
